(19) United States
(12) Patent Application Publication
(10) Pub. No.: US 2008/0277763 A1
(43) Pub. Date: Nov. 13, 2008

(54) Abrupt Metal-Insulator Transition Wafer, and Heat Treatment Apparatus and Method For the Wafer

(75) Inventors: Hyun Tak Kim, Daejeon-city (KR); Byung Gyu Chae, Daejeon-city (KR); Kwang Yong Kang, Daejeon-city (KR); Sun Jin Yun, Daejeon-city (KR)

Correspondence Address: CANTOR COLBURN, LLP, 20 Church Street, 22nd Floor, Hartford, CT, 06103, US

(73) Assignee: Electronics and Telecommunications Research - Institute, Daejeon-city (KR)

(21) Appl. No.: 11/997,050

(22) PCT Filed: Jul. 4, 2006
(86) PCT No.: PCT/KR06/02605

§ 371 Date: Jan. 28, 2008

(30) Foreign Application Priority Data
Jul. 28, 2005 (KR) 10-2005-0069119
Feb. 17, 2006 (KR) 10-2006-0015635

(51) Int. Cl. H01L 21/322; H01L 29/12; H05B 3/68

(52) U.S. Cl. 257/613; 219/444.1; 438/796; 257/E29.068; 257/E21.317

(57) ABSTRACT

Provided are a wafer with the characteristics of abrupt metal-insulator transition (MIT), and a heat treatment apparatus and method that make it possible to mass-produce a large-diameter wafer without directly attaching the wafer to a heater or a substrate holder. The heat treatment apparatus includes a heater applying heat to a wafer having the characteristics of abrupt MIT and one surface covered with a thermally opaque film, and a plurality of fixing units formed along an edge portion of a top surface of the heater to fix the wafer to the heater.

### CROSS-REFERENCE TO RELATED PATENT APPLICATION

This application claims the benefit of Korean Patent Application Nos. 10-2005-0069119 filed on Jul. 28, 2005 and 10-2006-0015635, filed on Feb. 17, 2006, in the Korean Intellectual Property Office, the disclosure of which are incorporated herein in their entirety by reference.

### BACKGROUND OF THE INVENTION

1. Field of the Invention

The present invention relates to a wafer with the characteristics of abrupt metal-insulator transition (MIT) and a heat treatment apparatus and method for the same, and more particularly, to a wafer with the characteristics of abrupt MIT, and an apparatus and method for performing a uniform mass heat treatment process on the wafer.

2. Description of the Related Art

Recently, memory devices using a phase change material have been actively researched and developed. An example of such a memory device is a phase change memory (PCM) device that changes from a crystalline phase into an amorphous phase at a high temperature. This structural phase change, however, causes atoms to change position in the PCM device, thus making it impossible to provide a high switching speed. Therefore, the PCM device is inadequate for use as a high speed switching device.

To solve this problem, an abrupt MIT device using an abrupt metal-insulator transition material is disclosed in U.S. Pat. No. 6,624,463. Abrupt MIT material is characterized in that a transition from an insulator to a metal occurs not continuously but abruptly by low-concentration holes added to a Mott-Brinkman-Rice insulator. The hole-driven MIT theory has been proposed in the paper “New Trends in Superconductivity” [NATO Science Series Vol II/67 (Kluwer, 2002) p137, author: Hyun-Tak Kim] or at http://xxx.lanl.gov/abs/cond-mat/0110112.

Abrupt MIT material can be produced using a variety of methods including a sputtering method, a laser deposition method, a sol-gel method, and an atom deposition method. A typical example of abrupt MIT material is a vanadium oxide (specifically, VO₂) that has a good crystallinity and undergoes abrupt MIT. However, it is difficult to mass-produce a VO₂ thin film. The reason for this is that the amount of oxygen used for producing the VO₂ thin film is very difficult to adjust because the vanadium oxide has various phases. Therefore, a heat treatment method capable of adjusting the amount of oxygen while enhancing crystallinity is essential for producing the VO₂ thin film.

In a conventional VO₂ thin film production method, a vanadium oxide that contains a relatively-large amount of oxygen and can be easily produced, for example, a V₂O₅ thin film, is first attached to a substrate holder or a heater coated with a liquid silver (Ag) paste. Thereafter, using the heater, the V₂O₅ thin film is heated to remove oxygen contained in V₂O₅, thereby forming a VO₂ thin film. This conventional VO₂ thin film production method is adequate for forming a VO₂ thin film with a small area of, for example, 2×2 cm². The reason for this is that the 2×2 cm² VO₂ thin film can be easily removed from the heater or the substrate holder after completion of heat treatment.

However, a VO₂ thin film wafer with a diameter of 2 or more inches is difficult to remove from the heater or the substrate holder. That is, during the removal process, a residual stress may occur in the VO₂ thin film wafer or the VO₂ thin film wafer may even be broken. Therefore, a method capable of mass-producing a VO₂ thin film without adhering it to the heater or the substrate holder is required.

### SUMMARY OF THE INVENTION

The present invention provides a wafer with the characteristics of abrupt metal-insulator transition (MIT) and an apparatus for performing a heat treatment operation on the wafer, which make it possible to mass-produce a large-diameter wafer without directly attaching it to a heater or a substrate holder.

The present invention also provides a method for performing a heat treatment operation on a thin film with the characteristics of abrupt MIT using the above apparatus.

According to an aspect of the present invention, there is provided a wafer with the characteristics of abrupt MIT, the wafer including: a MIT film with the characteristics of abrupt MIT on the substrate; and a metal layer formed by coating or depositing a paste with a good electrical and thermal conductivity on the substrate.

According to another aspect of the present invention, there is provided a heat treatment apparatus including: a heater applying heat to a wafer having the characteristics of abrupt MIT and one surface covered with a thermally opaque film; and a plurality of fixing units formed along an edge portion of a top surface of the heater to fix the wafer to the heater.

The thermally opaque film may absorb heat and the absorbed heat may be uniformly distributed over the thermally opaque film. The thermally opaque film may be formed using a thin metal film or a metal-containing paste. The thermally opaque film may be a single-layer or multi-layer film formed using one selected from the group consisting of Li, Be, C, Na, Mg, Al, K, Ca, Sc, Ti, V,. Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Tb, Dy, Ho, Er, Tm, Yb, Lu, Th, U, Np, Pu, a compound thereof, an oxide thereof, and an oxide of the compound.

Each of the fixing units may include a screw-type body rotatably fixed to the edge portion of the top surface of the heater, and a handle for rotating the screw-type body. Each of the fixing units may be fixed to the edge portion of the top surface of the heater and may be formed of an elastic material.

The wafer may include a substrate formed of a material with the characteristics of abrupt MIT. Here, the material with the characteristics of abrupt MIT may be a p-type inorganic compound semiconductor or insulator material to which low-concentration holes are added, a p-type organic semiconductor or insulator material to which low-concentration holes are added, or an oxide thereof; and the p-type inorganic compound semiconductor or insulator material may include at least one of a semiconductor element including a group III-V compound or a group II-VI compound, a transition metal element, a rare earth element, and a lanthanum-based element.

The heat treatment apparatus may further include a ring-type fixing plate disposed between the heater and the fixing units along the edge portion of the top surface of the heater while covering an edge portion of the wafer.

According to another aspect of the present invention, there is provided a heat treatment method including: preparing a substrate with the characteristics of abrupt MIT; covering a first surface of the substrate with a thermally opaque film to form a wafer; fixing the wafer to the heater with a plurality of fixing units in such a way that the thermally opaque film is exposed; and applying heat to the wafer.

The thermally opaque film may be formed by deposing a thin metal film on the first surface of the wafer or by coating the first surface of the wafer with a metal-containing paste. The heat may be generated using ultraviolet rays.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a wafer having a substrate coated with an opaque film according to an embodiment of the present invention;

FIG. 2A is a perspective view of a heat treatment apparatus according to an embodiment of the present invention;

FIG. 2B is a sectional view taken along a line 2B-2B of FIG. 2A according to an embodiment of the present invention;

FIG. 2C is a plan view of a fixing plate in FIG. 2A according to an embodiment of the present invention;

FIG. 3 is a flow diagram illustrating a heat treatment process using the heat treatment apparatus of FIG. 2A, according to an embodiment of the present invention; and

FIG. 4 is a graph illustrating a resistance-to-temperature relationship of a VO₂ thin film having undergone the heat treatment process of FIG. 3.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their description will be omitted.

There are various purposes in performing a heat treatment process on a thin film with the characteristics of abrupt MIT. For example, the heat treatment operation is performed so as to adjust the amount of an element in the thin film, or so as to remove a defect in the thin film. Although the present invention proposes a heat treatment apparatus and method for adjusting the amount of, for example, oxygen in a VO₂ thin film, the heat treatment process may be performed for many other purposes.

The aim of the present invention is to adjust the amount of oxygen in a vanadium oxide film, and an apparatus and method are disclosed for producing a VO₂ thin film by removing oxygen from, for example, a V₂O₅ thin film. It is very difficult to remove oxygen from the V₂O₅ thin film without adhering the V₂O₅ thin film to a heater or a substrate holder by a liquid silver paste. In general, when a material such as a bulk-type ceramic is heated in a vacuum, oxygen is partially removed from the material.

However, in the case of a wafer with a diameter of 2 or more inches, the amount of oxygen in the wafer is hardly adjusted even when the wafer is heated. The reason for this is that heat applied to a transparent or opaque wafer does not remain in the wafer but is dissipated outside.

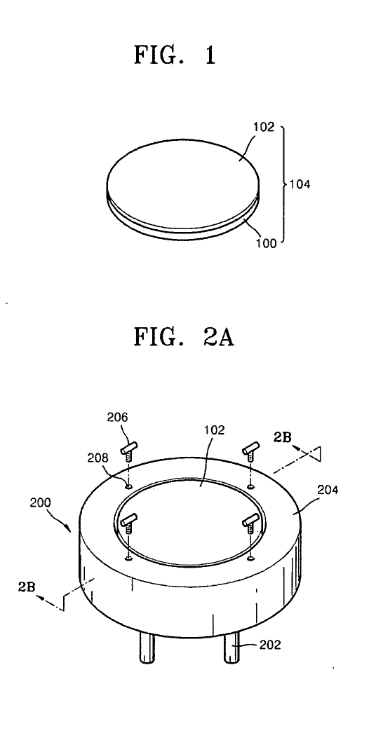

FIG. 1 is a perspective view of a wafer 104 having a substrate 100 coated with an opaque film according to an embodiment of the present invention.

Referring to FIG. 1, the substrate 100 is formed of a material with the characteristics of abrupt MIT. The material with the characteristics of abrupt MIT may be a p-type inorganic compound semiconductor or insulator material to which low-concentration holes are added, a p-type organic semiconductor or insulator material to which low-concentration holes are added, or an oxide thereof. For example, the p-type inorganic compound semiconductor or insulator material may include at least one of a semiconductor element (e.g., a group III-V compound and a group Il-VI compound), a transition metal element, a rare earth element, and a lanthanum-based element.

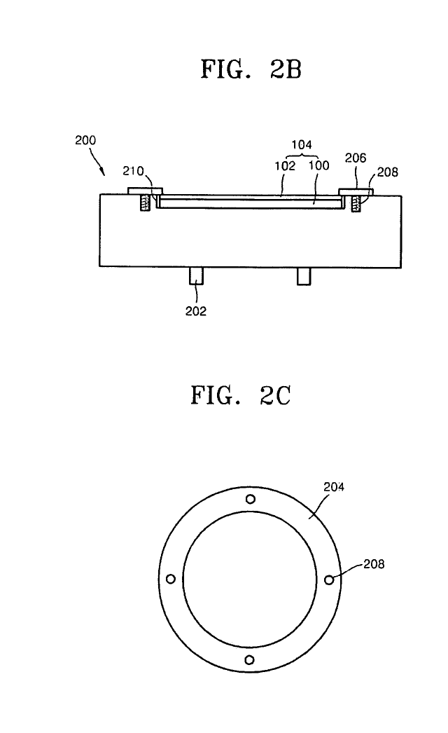

An upper surface of the substrate 100 is covered with a thermally opaque film 102. Heat hardly penetrates a thermally opaque film but is absorbed into and uniformly distributed throughout the film. The thermally opaque film 102 is a thermally conductive film that distributes absorbed heat throughout the thermally opaque film 102. Accordingly, the thermally opaque film 102 receives heat from a heater 200 (FIG. 2A) and uniformly distributes the received heat throughout the substrate 100, thereby obtaining a uniform heat treatment process.

The thermally opaque film 102 may be formed of a thin metal film or a metal-containing paste. For example, the thermally opaque film 102 may be a single-layer or multi-layer film formed using one selected from the group consisting of Li, Be, C, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Tb, Dy, Ho, Er, Tm, Yb, Lu, Th, U, Np, Pu, a compound thereof, an oxide thereof, and an oxide of the compound.

FIG. 2A is a perspective view of a heat treatment apparatus according to an embodiment of the present invention. FIG. 2B is a sectional view taken along a line 2B-2B of FIG. 2A according to an embodiment of the present invention. FIG. 2C is a plan view of a fixing plate in FIG. 2A according to an embodiment of the present invention.

Referring to FIGS. 2A through 2C, the heat treatment apparatus includes a heater 200 applying heat to the wafer 104, and a plurality of fixing units 206 formed along an edge portion of a top surface of the heater 200 so as to fix the wafer 104 to the heater 200. Each of the fixing units 206 may include a screw-type body rotatably fixed into a fixing groove 208 formed along the edge portion of the top surface of the heater 200, and a handle for rotating the screw-type body. That is, the fixing unit 206 is configured to vertically move in the fixing groove 208. Although not illustrated in FIG. 2A, the fixing units 206 are fixed to the edge portion of the top surface of the heater 200, and may be formed of an elastic material.

The heater 200 may include a recessed region 210 recessed to a predetermined depth in a center portion of the top surface of the heater 200 to receive the wafer 104. The recessed region 210 may have a larger diameter than the wafer 104 such that gas (e.g., oxygen) generated at the wafer 104 can be discharged through a space formed between the circumference of the recessed region 210 and the wafer 104 disposed in the recessed region 210. In addition, between the heater 200 and the fixing unit 206, a ring-type fixing plate 204 may be disposed on the edge portion of the top surface of the heater 200 while covering an edge portion of the wafer 104 disposed in the recessed region 210. A reference numeral 202 denotes a conductive wire through which a voltage for generating heat is applied to the heater 200.

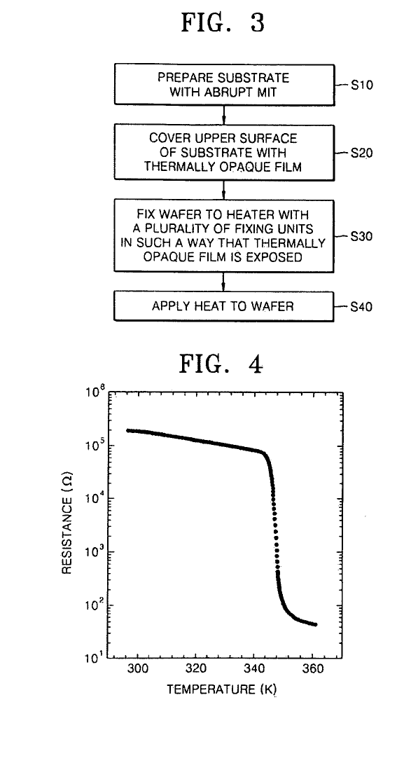

FIG. 3 is a flow diagram illustrating a heat treatment process using the heat treatment apparatus of FIG. 2A, according to an embodiment of the present invention.

Referring to FIG. 3, a substrate 100 with the characteristics of abrupt MIT is prepared in operation S10. The substrate 100 may be formed of a vanadium oxide, for example, VO₂. In operation S20, an upper surface of the substrate 100 is covered with a thermally opaque film 102. The thermally opaque film 102 may be formed by depositing a thin metal film on the upper surface of the substrate 100 or by coating the upper surface of the substrate 100 with a metal-containing paste. The substrate 100 covered with the thermally opaque film 102 is referred to as a wafer 104. In operation S30, the wafer 104 is fixed to the heater 200 with the fixing units 206 in such a way that the thermally opaque film 102 is exposed. If necessary, a separate substrate holder (not illustrated) may be installed in the heater 200. In operation S40, heat is applied to the heater 200. The heat may be generated using ultraviolet rays. A subsequent process may be performed after removing or without removing the thermally opaque film 102 from the wafer 104 having undergone the heat treatment.

FIG. 4 is a graph illustrating a resistance-to-temperature relationship of a VO₂ thin film having undergone the heat treatment process of FIG. 3.

Referring to FIG. 4, the VO₂ thin film has the resistance of an insulator when a temperature is below about 340 K. The resistance of the VO₂ thin film rapidly decreases as the temperature increases above about 340 K. Specifically, the resistance of the VO₂ thin film approaches about 105 Ω when the temperature is about 340 K, while decreasing below 102 Ω when the temperature is about 350 K. That is, when the heat treatment process of the present invention is applied, it is possible to obtain a large-diameter wafer that has a diameter of 2 or more inches and good MIT characteristics.

As described above, according to the present invention, a wafer with characteristics of abrupt MIT is covered with a thermally opaque film and heat is applied to the wafer using a heater. Accordingly, it is possible to mass-produce a large-diameter wafer without directly attaching it to the heater or a substrate holder.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wafer with the characteristics of abrupt metal-insulator transition (MIT), the wafer comprising:
a substrate with the characteristics of abrupt MIT; and
a metal layer formed by coating or depositing a paste with good electrical and thermal conductivity on the substrate.

2. The wafer of claim 1, wherein the metal layer comprises a single-layer or multi-layer film formed using one selected from the group consisting of Li, Be, C, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Tb, Dy, Ho, Er, Tm, Yb, Lu, Th, U, Np, Pu, a compound thereof, an oxide thereof, and an oxide of the compound.

3. A heat treatment apparatus comprising:
a heater applying heat to a wafer having the characteristics of abrupt MIT and one surface covered with a thermally opaque film; and
a plurality of fixing units formed along an edge portion of a top surface of the heater to fix the wafer to the heater.

4. The heat treatment apparatus of claim 3, wherein the thermally opaque film absorbs heat and the absorbed heat is uniformly distributed throughout the thermally opaque film.

5. The heat treatment apparatus of claim 3, wherein the thermally opaque film is formed of a thin metal film or a metal-containing paste.

6. The heat treatment apparatus of claim 3, wherein the thermally opaque film is a single-layer or multi-layer film formed using one selected from the group consisting of Li, Be, C, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Tb, Dy, Ho, Er, Tm, Yb, Lu, Th, U, Np, Pu, a compound thereof, an oxide thereof, and an oxide of the compound.

7. The heat treatment apparatus of claim 3, wherein each of the fixing units comprises a screw-type body rotatably fixed to the edge portion of the top surface of the heater, and a handle for rotating the screw-type body.

8. The heat treatment apparatus of claim 3, wherein each of the fixing units is fixed to the edge portion of the top surface of the heater and is formed of an elastic material.

9. The heat treatment apparatus of claim 3, wherein the wafer comprises a substrate formed of a material with the characteristics of abrupt MIT;
the material with the characteristics of abrupt MIT is a p-type inorganic compound semiconductor or insulator material to which low-concentration holes are added, a p-type organic semiconductor or insulator material to which low-concentration holes are added, or an oxide thereof; and
the p-type inorganic compound semiconductor or insulator material comprises at least one of a semiconductor element including a group III-V compound or a group II-VI compound, a transition metal element, a rare earth element, and a lanthanum-based element.

10. The heat treatment apparatus of claim 3, wherein the substrate is formed of a vanadium oxide.

11. The heat treatment apparatus of claim 3, wherein the heater has a recessed region recessed to a predetermined depth in a center portion of the top surface thereof to receive the wafer.

12. The heat treatment apparatus of claim 11, wherein the recessed region has a larger diameter than the wafer such that gas generated at the wafer can be discharged through a space formed between the circumference of the recessed region and the wafer disposed in the recessed region.

13. The heat treatment apparatus of claim 3, further comprising a ring-type fixing plate disposed between the heater and the fixing units along the edge portion of the top surface of the heater while covering an edge portion of the wafer disposed in the recessed region.

14. A heat treatment method comprising:
preparing a substrate with the characteristics of abrupt MIT;
covering a first surface of the substrate with a thermally opaque film to form a wafer;
fixing the wafer to the heater with a plurality of fixing units in such a way that the thermally opaque film is exposed; and
applying heat to the wafer.

15. The heat treatment method of claim 14, wherein the thermally opaque film is formed by deposing a thin metal film on the first surface of the wafer or by coating the first surface of the wafer with a metal-containing paste.

16. The heat treatment method of claim 14, wherein the thermally opaque film is a single-layer or multi-layer film formed using one selected from the group consisting of Li, Be, C, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Tb, Dy, Ho, Er, Tm, Yb, Lu, Th, U, Np, Pu, a compound thereof, an oxide thereof, and an oxide of the compound.

17. The heat treatment method of claim 14, wherein the substrate is formed of a material with the characteristics of abrupt MIT;
the material with the characteristics of abrupt MIT is a p-type inorganic compound semiconductor or insulator material to which low-concentration holes are added, a p-type organic semiconductor or insulator material to which low-concentration holes are added, or an oxide thereof; and
the p-type inorganic compound semiconductor or insulator material comprises at least one of a semiconductor element including a group III-V compound or a group II-VI compound, a transition metal element, a rare earth element, and a lanthanum-based element.

18. The heat treatment method of claim 14, wherein the heat is generated using ultraviolet rays.
